(19) United States
(12) Patent Application Publication
(10) Pub. No.: US 2016/0268479 A1
(43) Pub. Date: Sep. 15, 2016

(54) MULTI-LAYERED TRANSPARENT ELECTRODE HAVING METAL NANO HOLE PATTERN LAYER

(71) Applicants: GWANGJU INSTITUTE OF SCIENCE AND TECHNOLOGY, Gwangju (KR); DAEGU GYEONGBUK INSTITUTE OF SCIENCE AND TECHNOLOGY, Daegu (KR)

(72) Inventors: Seong-Ju Park, Gwangju (KR); Sun-hye Song, Gwangju (KR); Sang-Hyun Hong, Gwangju (KR); Hyo-Ju Lee, Gwangju (KR); Jang-Won Kang, Gwangju (KR); Chang-Hee Cho, Daegu (KR); Bo-Kyung Song, Bucheon-si (KR)

(21) Appl. No.: 14/983,376

(22) Filed: Dec. 29, 2015

(30) Foreign Application Priority Data
Mar. 13, 2015 (KR) 10-2015-0035096

(51) Int. Cl. H01L 33/42

(52) U.S. Cl. CPC H01L 33/42

(57) ABSTRACT

The present invention relates to a multi-layered transparent electrode having a metal nano hole pattern layer. The multi-layered transparent electrode may include a lower oxide layer, a metal nano hole pattern layer disposed on the lower oxide layer, and an upper oxide layer disposed on the metal nano hole pattern layer. By adjusting the pattern period and nano hole size of the metal nano hole pattern layer, transmittance of the multi-layered transparent electrode may be enhanced in a specific wavelength region through surface plasmon, which is a phenomena caused by the metal nanohole pattern layer. In addition, optimized sheet resistance may be implemented in a multi-layered transparent electrode having the metal nano hole pattern layer by adjusting the hole size. Thereby, electrical characteristics of a device employed the multi-layered transparent electrode may be enhanced.

### CROSS REFERENCE TO RELATED APPLICATION

This application claims the benefit of Korean Patent Application No. 10-2015-0035096, filed on Mar. 13, 2015, entitled “MULTI-LAYERED TRANSPARENT ELECTRODE HAVING METAL NANO HOLE PATTERN LAYER”, which is hereby incorporated by reference in its entirety into this application.

### BACKGROUND

1. Technical Field

The present invention relates to a transparent electrode and, more particularly, to a multi-layered transparent electrode having a metal nano hole pattern layer.

2. Description of the Related Art

A transparent electrode refers to an oxide-based degenerate semiconductor electrode having high light transmittance (greater than or equal to 80%) in the visible light region and high electrical conductivity. Transparent electrodes, which have been used as key components of display devices such as liquid crystal displays (LCDs) and organic light-emitting diode (OLED) displays, are recently widely used as electrodes of displays, touch panels and solar cells.

Currently, indium tin oxide (ITO), which is a wide band gap ranging from about 3.5 eV to about 4.3 eV, is most widely used as a material of the transparent electrode. The ITO has excellent electrical conductivity and exhibits chemical stability and high light transmittance at room temperature/atmospheric pressure. In addition, the ITO can be easily fabricated to have a wide area through a simple process such as sputtering.

However, with increase in demand for indium (In), which is the main material of ITO, and limited indium deposits, the material price of ITO has been persistently increasing. In addition, when transparent conductive oxide materials such as ITO, indium zinc oxide (IZO) and F-doped tin oxide (FTO) are formed to have a thickness greater than or equal to 100 nm, they have low resistance to bending or distortion of a substrate, and are thus easily fractured. Thereby, they have degraded electrical characteristics and cannot be applied to a high integrated circuit or an electronic device having a large area. Particularly, ITO having high conductivity is essentially processed at a temperature greater than or equal to an activation temperature (200° C.) of tin (Sn) which is a dopant material, and accordingly cannot be applied to a flexible device. Moreover, when ITO is exposed to light having a wavelength less than or equal to about 400 nm, light absorption occurs in ITO due to the unique bandgap size of the ITO, and thus light transmittance of ITO suddenly decreases to a level lower than about 80%. Accordingly, application of ITO to a ultraviolet (UV) LED degrades efficiency.

To solve the aforementioned problems, research has been conducted on a transparent electrode having a multi-layered structure of oxide/metal layer/oxide as a material to replace ITO. It has been reported that this multi-layered transparent electrode has high transmittance greater than or equal to 80% and very low sheet resistance (20 Ω/sq) in the visible light region, while having light transmittance less than 80% for wavelengths less than or equal to about 400 nm. For this reason, the multi-layered transparent electrode is rarely applicable to a UV device as in the case of conventional ITO.

### BRIEF SUMMARY

It is an aspect of the present invention to provide a transparent electrode which has a low sheet resistance and high light transmittance in the visible light region and is thus applicable to various optical devices.

In accordance with one aspect of the present invention, a multi-layered transparent electrode having a metal nano hole pattern layer includes a lower oxide layer, a metal nano hole pattern layer disposed on the lower oxide layer, and an upper oxide layer disposed on the metal nano hole pattern layer.

The lower oxide layer and the upper oxide layer may be formed of at least one oxide selected from among indium tin oxide (ITO), aluminum-doped zinc oxide (AZO), gallium-doped zinc oxide (GZO), zinc oxide (ZnO) and magnesium zinc oxide (MgZnO).

The lower oxide layer and the upper oxide layer may be formed of the same oxide.

The metal nano hole pattern layer may be formed of at least one mental selected from among gold (Au), silver (Ag), letting them (Pt), copper (Cu) and an alloy of two or more thereof.

A size of holes of the metal nano hole pattern layer may be between 100 nm and 180 nm.

A pattern period of the metal nano hole pattern layer may be between 200 nm and 300 nm.

Thickness of the metal nano hole pattern layer is between 4 nm and 20 nm.

Transmittance of the multi-layered transparent electrode is between 80% and 90%.

According to embodiments of the present invention, by adjusting the pattern period and hole size of a metal nano hole pattern layer, transmittance of the multi-layered transparent electrode may be enhanced in a specific wavelength region through surface plasmon, which is a phenomena caused by the metal nanohole pattern layer.

In addition, optimized sheet resistance may be implemented in a multi-layered transparent electrode having the metal nano hole pattern layer by adjusting the hole size.

Effects of the present invention are not limited to those described above and other effects of the present invention will be apparent to those skilled in the art from the following descriptions.

### BRIEF DESCRIPTION OF THE DRAWINGS

FIG. 1 is a mimetic diagram illustrating a multi-layered transparent electrode according to an embodiment of the present invention.

FIG. 2 is a diagram illustrating a metal nano hole pattern layer having periodic hexagonal arrays according to an embodiment of the present invention.

FIG. 3 is a graph depicting comparison between transmittance spectrum of transparent electrodes of Embodiment 1 and Comparative Example 1.

FIG. 4 is a graph depicting comparison between transmittance spectra of transparent electrodes of Embodiment 1 and Comparative Example 2.

FIG. 5 is a graph depicting a result of simulation of transmittance spectra according to pattern periods of Embodiment 1.

FIG. 6 is a graph depicting comparison of transmittance spectra according to thickness of the metal nano hole pattern layer and the hole size in Embodiment 1.

### DETAILED DESCRIPTION

Hereinafter, embodiments of the present invention will be described in detail with reference to the accompanying drawings.

Various modifications and variations can be made in the present invention. Exemplary embodiments will be described in detail below with reference to the accompanying drawings. It should be understood that the present invention is not limited to the following embodiments, and that the embodiments are provided for illustrative purposes only. The scope of the invention should be defined only by the accompanying claims and equivalents thereof.

It will be appreciated that for simplicity and clarity of illustration, layers and regions have not necessarily been drawn to scale in the drawings. Wherever possible, the same reference numbers will be used throughout the specification to refer to the same or like parts.

The president invention may provide a multi-layered transparent electrode having a metal nano hole pattern layer. Specifically, the multi-layered transparent electrode may include a lower oxide layer, a metal nano hole pattern layer disposed on the lower oxide layer, and an upper oxide layer.

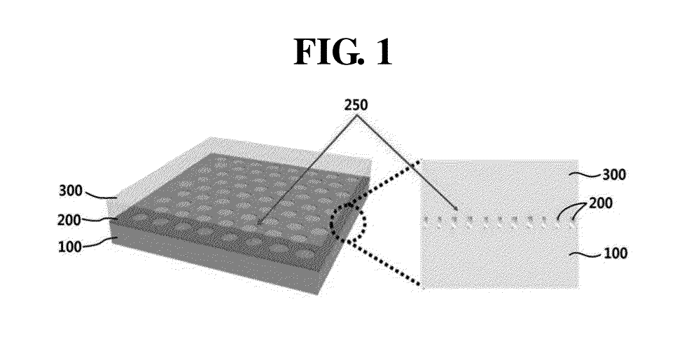

FIG. 1 is a mimetic diagram illustrating a multi-layered transparent electrode according to an embodiment of the present invention.

Referring to FIG. 1, the multi-layered transparent electrode may be disposed on a substrate 10 in this embodiment.

The substrate 10, which is a supporter capable of supporting the multi-layered transparent electrode, may employ any kind of substrates applicable to various electronic devices. The substrate 10 may employ a glass substrate, a sapphire substrate, or a flexible transparent substrate formed of, for example, polyehtylene naphthalate (PEN), polyethylene terephthalate (PET), polycarbonate (PC), Polyethylene sulfone (PES), polyimide (PI), polyarylate (PAR), polycyclic olefin (PCO), Polymethyl metacrylate (PMMA), crosslinking type epoxy), or crosslinking type urethane. However embodiments of the present invention are not limited thereto.

The lower oxide layer 100 and the upper oxide layer 300 disposed on the substrate may be formed of at least one oxide selected from among indium tin oxide (ITO), aluminum-doped zinc oxide (AZO), gallium-doped zinc oxide (GZO), zinc oxide (ZnO) and magnesium zinc oxide (MgZnO). In one embodiment of the present invention, thicknesses of the lower oxide layer 100 and the upper oxide layer 300 may be between 10 nm and 100 nm. If the thickness of the lower oxide layer 100 and the upper oxide layer 300 exceeds 100 nm, the lower oxide layer and the upper oxide layer may be cracked and thus electrical and optical characteristics of the multi-layered transparent electrode may be degraded.

According to an embodiment of the present invention, the lower oxide layer 100 and the upper oxide layer 300 may be formed of the same oxide. Specifically, as shown in FIG. 1, when the lower oxide layer 100 and the approximate layer 300 are formed of the same oxide and thus have the same dielectric constant, the resonance wavelength between the lower side layer 100 and the metal nano hole pattern layer 200 is equal to the resonance wavelength between the metal nano hole pattern layer 200 and the upper oxide layer 300. Thereby, reflectance may be lowered, and transmittance of the multi-layered transparent electrode may be enhanced, which will be described in detail based on an embodiment and drawings.

If the lower oxide layer and the upper oxide layer are formed of different oxides, they have different dielectric constants and thus a surface plasmon resonance wavelength between the lower oxide layer and the metal nano hole pattern layer differs from the surface plasmon resonance wavelength between the metal nano hole pattern layer and the upper oxide layer. Thereby, enhancement of transmittance is hardly expected.

As the multi-layered transparent electrode having a metal nano hole pattern layer is formed by depositing the upper oxide layer 300 onto the metal nano hole pattern layer 200, conventional problems such as damage to the transparent electrode caused by displacement of a metal layer disposed on the transparent electrode and a chemical stability-related problem may be addressed.

For the multi-layered transparent liquid electrode of the present invention, characteristics of conventional ITO may be maintained, while thicknesses of the upper oxide layer and the lower side layer decrease. Accordingly, the multi-layered transparent electrode can be applied to a device requiring flexibility.

Formation of the lower oxide layer 100 on the substrate 10 and the formation of the upper oxide layer 300 on the metal nano hole pattern layer 200 may be implemented using a well-known oxide deposition method. For example, the lower oxide layer 100 and the upper oxide layer 300 may be formed through sputtering, chemical vapor deposition (CVD), thermal evaporation, e-beam, spray pyrolysis or a sol-gel process. However, embodiments of the present invention are not limited thereto.

The metal nano hole pattern layer 200 disposed on the lower oxide layer 100 may be a metal layer having a pattern structure in which a plurality of nanoscale holes are periodically arranged. The metal nano hole pattern layer 200 may include at least one metal material selected from among gold (Au), silver (Ag), platinum (Pt), copper (Cu) an alloy of two or more thereof.

According to one embodiment of the present invention, the size of holes of the metal nano hole pattern layer 200 may be between 100 nm and 118 nm. If the size of the holes of the metal nano hole pattern layer 206 exceeds 180 nm, metals are far apart from each other and thus high sheet resistance may be produced. In addition, the lowest sheet resistance (about 11.5 Ω/sq) may be obtained when the size of the holes of the metal nano hole pattern layer 200 is 100 nm. Accordingly, electrical characteristics of the multi-layered transparent electrode may be optimized within the aforementioned range of hole size. As such, the sheet resistance of the metal nano hole pattern layer 200 can be controlled to enhance electrical characteristics of the multi-layered transport electrode by adjusting the size of the nano holes.

Specifically, the electrical characteristics of the multi-layered transparent electrode having the nano hole pattern layer of the present invention may be defined as follows.

$$\frac{1}{{R}_{S}} = \frac{1}{{R}_{METAL}} + \frac{1}{{R}_{TCO}} \qquad Equation 1$$

In Equation 1, R_{S} denotes sheet resistance of the multi-layered transparent electrode, R_{METAL} denotes sheet resistance of the multi-layered transparent electrode, R_{TCO} denotes sheet resistance of the upper oxide layer and the lower oxide layer. As can be seen from Equation 1, the sheet resistance of the multi-layered transparent electrode is determined according to sheet resistances of the metal nano hole pattern layer, the upper oxide layer and the lower oxide layer which constitute the multi-layered transparent electrode. According to the present invention, the lower oxide layer and the upper oxide layer of the multi-layered transparent electrode are deposited at room temperature without a separate doping process, and accordingly resistance thereof are very high compared to that of the metal nano hole pattern layer. Specifically, resistance of the lower oxide layer and the upper oxide layer can be expressed as Equation 2 given below.

R_{TCO}>>R_{METAL},R_{S}≈R_{METAL} Equation 2

It can be seen from the above equation that overall sheet resistance of the multi-layered transparent electrode is determined by the metal nano hole pattern layer provided to the multi-layered transparent electrode. Relevant details will be described below based on an embodiment and drawings.

According to an embodiment of the present invention, the pattern period of the metal nano hole pattern layer 200 may be between 200 nm and 300 nm. The pattern period of the metal nano hole pattern layer 200 refers to a distance (space) between that holes which are periodically arranged on the metal nano hole pattern layer 200. The electrical characteristics of the multi-layered transparent electrode may be optimized in the aforementioned range. By adjusting the pattern period of the metal nano hole pattern layer, transmittance in a specific wavelength region of the multi-layered transparent electrode having the metal nano hole pattern layer may be enhanced.

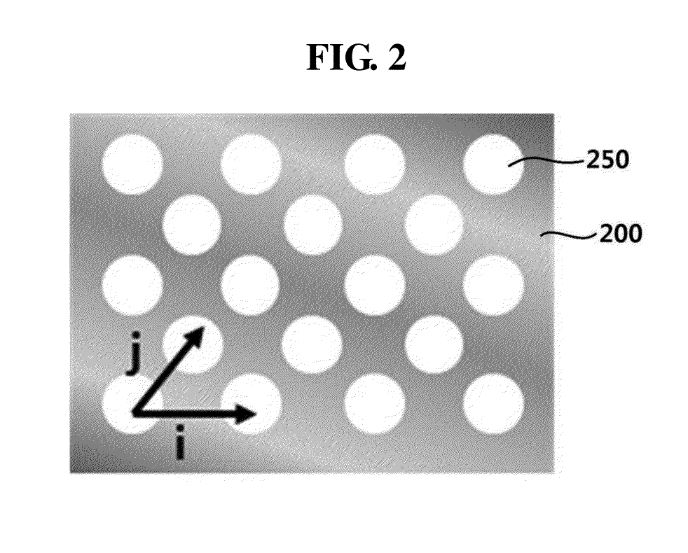

FIG. 2 is a diagram illustrating a metal nano hole pattern layer patterned by periodically arranging a plurality of nano holes in hexagonal arrays according to an embodiment of the present invention. As shown in FIG. 2, when nano holes 250 of the metal nano hole pattern layer 200 are patterned in hexagonal arrays, it is generally known that a resonance wavelength range is determined by Equation 3 given below (William L. Barnes et al, Nature, 424, 2003).

$$λ = \frac{P}{\sqrt{\frac{4}{3} ( {i}^{2} + ij + {j}^{2} )}} \times \frac{\sqrt{{ɛ}_{metal} {ɛ}_{TCO}}}{\sqrt{{ɛ}_{metal} + {ɛ}_{TCO}}} \qquad Equation 3$$

In Equation 3, λ denotes a resonance wavelength at which resonance occurs, P denotes a pattern period, and ∈ₘₑₜₐₗ and ∈_{TCO} denote dielectric constants of the upper oxide layer and lower oxide layer of the metal nano hole pattern layer. According to Equation 3, transmittance of the multi-layered transparent electrode of the present invention may be enhanced by inducing resonance in a specific wavelength region through adjustment of types of oxide layers having dielectric constants and the pattern period of the holes arranged on the metal nano hole pattern layer 200. Details will be described below based an embodiment and a drawing.

According to one embodiment of the present invention, thickness of the metal nano hole pattern layer 200 may be between 4 nm and 20 nm. If the thickness of the metal nano hole pattern layer 200 is less than 4 nm, an island structure may be produced to degrade electrical characteristics of the pattern layer. In consideration of the fact that the skin depth by which light penetrates metal is less than or equal to about 20 nm, the metal nano hole pattern layer 200 may be formed to have a thickness less than 20 nm. Details will be described below based on an embodiment and a drawing.

Disposition of the metal nano hole pattern layer 200 on the lower oxide layer 100 can be implemented using a well-known metal layer deposition technique and lithography for patterning, and is not limited to a specific technique. For example, a metal layer to constitute the metal nano hole metal layer 200 may be formed on the lower oxide layer 100. The metal layer may be formed on the lower oxide layer 100 using a well-known metal layer deposition technique such as chemical vapor deposition (CVD), thermal evaporation, e-beam, or spray pyrolysis. Thereafter, a hole pattern having periodic arrays of a plurality of nano holes may be formed in the metal layer using lithography.

Transmittance of the metal nano hole pattern layer may be enhanced in a specific wavelength region through the surface plasmon phenomenon between the lower oxide layer and the metal nano hole pattern layer and between the metal nano hole pattern layer and the upper oxide layer, which is caused by disposing a metal nano hole pattern layer having periodic arrays of nanoscale holes between the lower oxide layer and the upper oxide layer and adjusting the pattern period and hole size of the metal nano hole pattern layer as described above. Specifically, in one embodiment of the present invention, transmittance of the multi-layered transparent electrode may be between 80% and 90%.

Hereinafter, to aid in understanding the present invention, a preferred embodiment will be described. It should be noted that the preferred embodiment is simply illustrative and does not limit the scope of the present invention.

### EMBODIMENT

### Embodiment 1

### A Multi-Layered Transparent Electrode Having a Metal Nano Hole Pattern Layer

A lower oxide layer is formed by depositing MgZnO onto a glass substrate. Silver (Ag) is formed on the lower oxide layer and then lithography is performed to form a metal hole pattern layer having periodic arrays of a plurality of nano holes. Herein, thicknesses of silver (Ag) of the respective specimens are 14 nm and 16 nm. The hole sizes defined for the respective specimens are 100 nm, 150 nm, and 180 nm. Pattern periods defined for the specimens are 20 nm and 300 nm. Thereafter, MgZnO is deposited onto the metal nano hole pattern layer formed of Ag to form an upper oxide layer to fabricate a multi-layered transparent electrode.

### Comparative Example 1

### A Transparent Electrode without an Upper Oxide Layer

The processes of Embodiment 1 except the process of forming an upper oxide layer are performed to fabricate a transparent electrode having a metal nano hole pattern layer formed of silver (Ag) on MgZnO. The thickness of silver is 14 nm, the pattern period of the hole pattern is 200 nm, and the hole size is 150 nm.

Table 1 below shows sheet resistance values according to hole sizes of the multi-layered transparent electrode of Embodiment 1.

TABLE 1

| Thickness of Metal nano hole | Hole size | Surface resistance |
|---|---|---|
| pattern layer (nm) | (nm) | (Ω/sq) |
| 14 | 0 | 7.7 |
| | 100 | 11.5 |
| | 150 | 14.6 |
| | 180 | >10⁶ |
| 16 | 0 | 7.7 |
| | 100 | 10.2 |
| | 150 | 12.5 |
| | 180 | 34 |

Referring to Table 1, when the size of the holes provide to the conventional transparent electrode is 0 nm, namely when a thin metal layer without any pattern is provided, low sheet resistance less than or equal to 10 Ω/sq is obtained. In the case of the multi-layered transparent electrodes of Embodiment 1 having a metal layer provided with a hole pattern, when the hole size is 180 nm, sheet resistance increases as the distance between the metals increases. However, when the hole size is between 100 nm and 150 nm, the metal fraction increases and sheet resistance drastically decreases to a value less than or equal to 20 Ω/sq. Thereby, the electrical characteristics of the multi-layered transparent electrode are enhanced. That is, sheet resistance of the multi-layered transparent electrode having the metal nano hole pattern layer is between 10 Ω/sq and 30 Ω/sq when the thickness of the metal nano hole pattern layer is between 2 nm and 60 nm. As such, the multi-layered transparent electrode having the metal nano hole pattern layer of the present invention can obtain optimized sheet resistance by adjusting the size of holes, and is accordingly expected to enhance electrical characteristics of an electronic device to which the multi-layered the transparent electrode is applied.

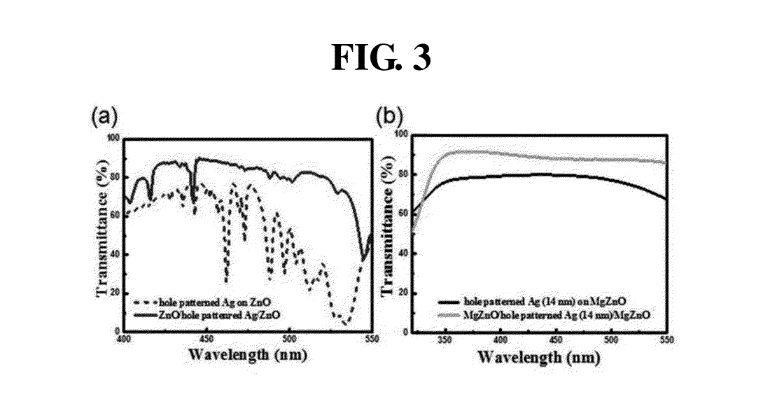

FIG. 3 is a graph depicting comparison between transmittance spectrum of transparent electrodes of Embodiment 1 and Comparative Example 1.

(a) in FIG. 3 is a graph depicting results of simulation of transmittance spectra of a transparent electrode provided with a lower oxide layer formed of ZnO and a metal nano hole pattern layer and a transparent electrode formed by sequentially disposing a lower oxide layer formed of ZnO, a metal nano hole pattern layer and an upper oxide layer formed of ZnO. Referring to (a) in FIG. 3, the transparent electrode having the upper ZnO oxide layer is higher transmittance than the transparent electrode which does not have an upper oxide layer, over almost the whole wavelength region.

(b) in FIG. 3 is a graph depicting comparison between transparent electrodes (for which the pattern hole size is 150 nm, the pattern period is 200 nm, and the thickness of silver (Ag) is 14 nm) fabricated using MgZnO according to Embodiment 1 and Comparative Example 1 under conditions similar to simulation of (a) in FIG. 3. It can be seen from (b) in FIG. 3 that transmittance of the multi-layered transparent electrode provided with the upper oxide layer of Embodiment 1 is 80% to 90% which is an increase of about 11% relative to transmittance of the transparent electrode of Comparative Example 1, which is not provided with an upper oxide layer.

Specifically, for the transparent electrode of Comparative Example 1 which is not provided with an upper oxide layer, an air layer is disposed on the metal nano hole pattern layer, and thus the dielectric constant between the inner layer and the metal nano hole pattern layer differs from the dielectric constant between the metal nano hole pattern layer and the lower oxide layer. Thereby, the surface plasmon resonance wavelength provided between the air layer and the metal nano hole pattern layer is different from the surface plasmon resonance wavelength provided between between the metal nano hole pattern layer and the lower oxide layer, and thus transmittance is rarely enhanced. On the other hand, if the upper oxide layer and the lower oxide layer are formed of the same oxide, MgZnO, the same resonance wavelength is provided between the lower oxide layer and the metal nano hole pattern layer and between the metal nano hole pattern layer and the upper side layer, and accordingly reflectance is reduced. Particularly, transmittance may be enhanced by more than 11% in the wavelength region below 550 nm.

### Comparative Example 2

### A Multi-Layered Transparent Electrode Having a Non-Patterned Metal Layer

The processes of Embodiment 1 except for the process of performing lithography on the metal layer of Ag formed on the lower oxide layer are performed to fabricate a multi-layered transparent electrode. The thickness of the metal layer is 14 nm.

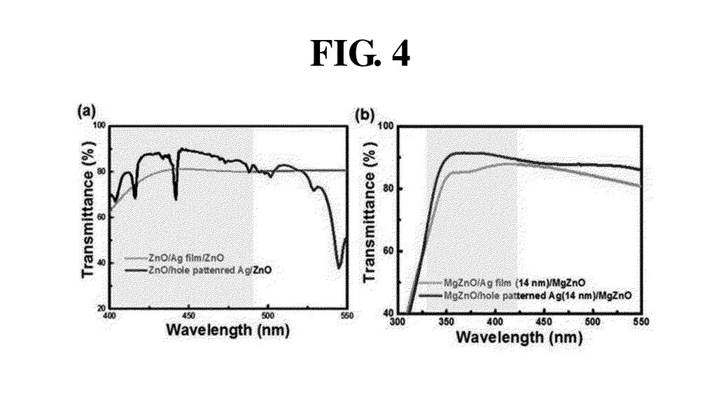

FIG. 4 is a graph depicting comparison between transmittance spectra of transparent electrodes of Embodiment 1 and Comparative Example 2.

(a) in FIG. 4 is a graph depicting results of simulation of transmittance spectra of a multi-layered transparent electrode provided with a lower ZnO oxide layer, an upper ZnO oxide layer, and a metal layer formed between the lower oxide layer and the upper oxide layer and a multi-layered transparent electrode provided with a lower ZnO oxide layer, an upper ZnO oxide layer, and a metal nano hole pattern layer, which is provided with a nano hole pattern and formed between the lower oxide layer and the upper oxide layer. Referring to (a) in FIG. 4, the multi-layered transparent electrode having the metal nano hole pattern layer provided with the nano pattern has transmittance increased by 7% from transmittance of the multi-layered transparent electrode having a metal layer without the pattern in the wavelength region below about 500 nm.

(b) in FIG. 4 is a graph depicting comparison between multi-layered transparent electrodes (for which the size of the nano hole pattern is 150 nm, the pattern period is 200 nm, and the thickness of silver (Ag) is 14 nm) fabricated using MgZnO according to Embodiment 1 and Comparative Example 1 under conditions similar to simulation of (a) in FIG. 4. It can be seen from (b) in FIG. 4 that transmittance of the multi-layered transparent electrode having a metal layer without a pattern according to Comparative Example 2 is low. In contrast, it can be seen from the figure that the multi-layered transparent electrode having a metal nano hole pattern layer with a nano hole pattern according to Embodiments 1 has transmittance increased by up to 7% from the transmittance of the multi-layered transparent electrode of Comparative Example 1 in the wavelength the region between 325 nm and 500 nm.

When a pattern of nanoscale holes arranged with a certain period is formed in the metal layer as in the case of Embodiment 1, it can be expected that transmittance will increase in the UV region between 300 nm and 400 nm or in the visible light region between 300 nm and 800 nm according to extraordinary optical transmission (EOT), which refers to a phenomenon of increase of transmittance in a specific wavelength region.

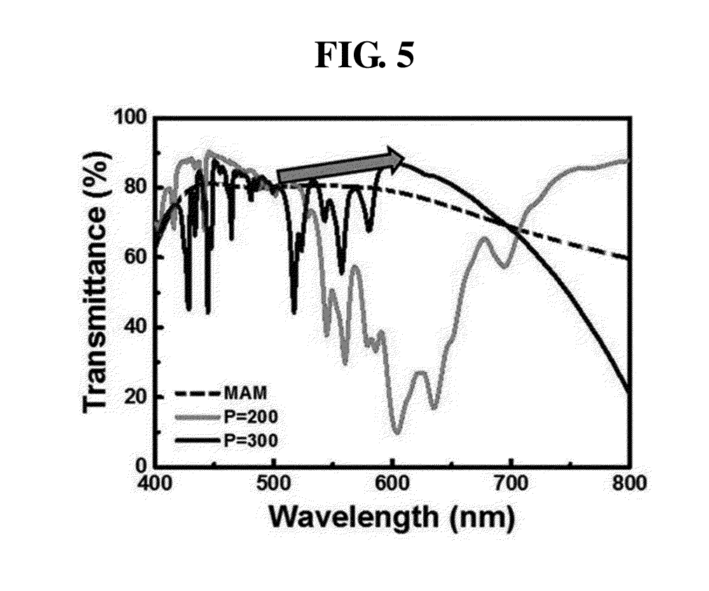

FIG. 5 is a graph depicting a result of simulation of transmittance spectrum according to pattern periods in Embodiment 1.

Referring to FIG. 5, when the pattern period is 200 nm, a resonance wavelength providing the maximum transmittance is present in the wavelength region around about 450 nm. When the pattern period is 300 nm, the resonance wavelength is shifted to a wavelength region around about 600 nm, and the transmittance spectrum is extended to a low-wavelength region as can be seen from Equation 3. That is, in the case of the multi-layered transparent electrode having a metal nano hole pattern layer according to the present invention, transmittance of the multi-layered transparent electrode may be enhanced in various wavelength regions by changing the resonance wavelength through adjustment of the pattern period.

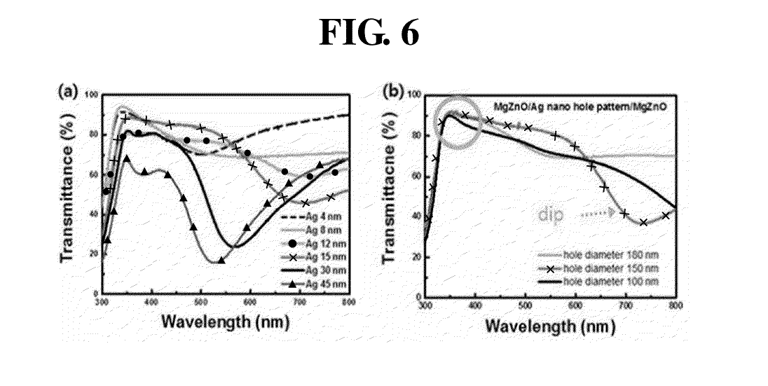

FIG. 6 is a graph depicting comparison of a transmittance spectrum according to thickness of the metal nano hole pattern layer and the hole size in Embodiment 1.

(a) in FIG. 6 is a graph depicting comparison between transmittance spectra according to thickness of a metal nano hole pattern layer formed of silver (Ag). As the thickness of the metal nano hole pattern layer increases, transmittance decreases drastically in the visible light region. Particularly, it can be seen from the figure that the maximum transmittance greater than or equal to 94% is obtained when the thickness of the layer is 8 nm. In addition, when the thickness of the metal nano hole pattern layer is less than or equal to 20 nm, which corresponds to the skin depth of Ag, transmittance greater than or equal to 80% can be secured in the visible light region. Therefore, it can be expected that enhancement of transmittance will be maximized in the visible light region when the thickness of the metal nano hole pattern layer formed of Ag is between 4 nm and 20 nm.

(b) in FIG. 6 shows transmittance spectra according to the hole size of the metal nano hole pattern layer formed of Ag. The wavelength region in which the maximum transmittance does not change. However, in the dip region where light is considerably absorbed due to local plasmon present in holes, when the size of nano holes decreases, the wavelength region is shifted to a long-wavelength region. That is, a multi-layered transparent electrode provided with the metal nano hole pattern layer according to the present invention may enhance transmittance not only for a specific wavelength but also in a wide wavelength region by optimizing the hole size of the metal nano hole pattern layer.

For the multi-layered transparent electrode of the present invention, the figure of merit (T10/R8) calculated in the wavelength region near 380 nm using transmittance and sheet resistance measured through the aforementioned embodiment, table and drawings is 0.0272/Ω. For a conventional transparent electrode (GZO/Ag/GZO) having a metal layer without a pattern, the calculated figure of merit is 0.0116/Ω. Herein, the figure of merit is a measure indicating a degree of excellence of a transparent electrode based on characteristics of transmittance and sheet resistance. The multi-layered transparent electrode of the present invention may have a figure of merit greater than or equal to twice the figure of merit of the conventional transparent electrode having a metal layer without a pattern.

In addition, the multi-layered transparent electrode having a metal nano hole pattern layer according to the present invention may address a problem with the conventional mesh type transparent electrode having a micro pattern, which increases sheet resistance as thickness of the metal layer decreases due to patterns. Specifically, when the metal layers are given the same thickness, the metal nano hole pattern layer of the present invention may have a larger metal friction due to the structure of a nanoscale hole pattern and lower sheet resistance than the mesh type transparent electrode having the micro pattern.

As such, it is expected that the multi-layered transparent electrode having a mental nano hole pattern layer according to present invention can be used as a transparent electrode for a device which is usable in the UV wavelength region. Additionally, as transmittance can be easily controlled in a wide wavelength region through adjustment of the pattern period, it is expected that the multi-layered transparent electrode is applicable to various kinds of optical devices including LEDs, solar cells and photodetectors in various wavelength regions.

Thus far, exemplary embodiments of the present invention have been described in detail with reference to the accompanying drawings. However, the present invention is not limited to the exemplary embodiments, and it is apparent that modifications and variations can be made within the scope of the present invention.

What is claimed is:

1. A multi-layered transparent electrode having a metal nano hole pattern layer, the multi-layered the transparent electrode comprising:
a lower oxide layer;
a metal nano hole pattern layer disposed on the lower oxide layer; and
an upper oxide layer disposed on the metal nano hole pattern layer.

2. The multi-layered transparent electrode according to claim 1, wherein the lower oxide layer and the upper oxide layer are formed of at least one oxide selected from among indium tin oxide (no), aluminum-doped zinc oxide (AZO), gallium-doped zinc oxide (GZO), zinc oxide (ZnO) and magnesium zinc oxide (MgZnO).

3. The multi-layered transparent electrode according to claim 1, wherein the lower oxide layer and the upper oxide layer are formed of the same oxide.

4. The multi-layered transparent electrode according to claim 1, wherein the metal nano hole pattern layer is formed of at least one mental selected from among gold (Au), silver (Ag), letting them (Pt), copper (Cu) and an alloy of two or more thereof.

5. The multi-layered transparent electrode according to claim 1, wherein a size of holes of the metal nano hole pattern layer is between 100 nm and 180 nm.

6. The multi-layered transparent electrode according to claim 1, wherein a pattern period of the metal nano hole pattern layer is between 200 nm and 300 nm.

7. The multi-layered transparent electrode according to claim 1, wherein thickness of the metal nano hole pattern layer is between 4 nm and 20 nm.

8. The multi-layered transparent electrode according to claim 1, wherein the metal nano hole pattern layer is patterned periodically.

9. The multi-layered transparent electrode according to claim 1, wherein the metal nano hole pattern layer is patterned in hexagonal arrays.

10. The multi-layered transparent electrode according to claim 1, wherein thickness of the lower oxide layer and the upper oxide layer is between 10 nm and 100 nm.
